(19) United States
(12) Patent Application Publication
(10) Pub. No.: US 2022/0029658 A1
(43) Pub. Date: Jan. 27, 2022

(54) WIRELESS REPEATER WITH FIR BASED CHANNEL EQUALIZER

(71) Applicant: RF DSP Inc., Irvine, CA (US)

(72) Inventors: Junyang Shen, Irvine, CA (US); Ping Liang, Newport Coast, CA (US); Dengkui Zhu, Beijing (CN); Boyu Li, Irvine, CA (US)

(73) Assignee: RF DSP Inc., Irvine, CA (US)

(21) Appl. No.: 17/305,865

(22) Filed: Jul. 15, 2021

Related U.S. Application Data
(63) Continuation of application No. 15/567,471, filed on Oct. 18, 2017.
(60) Provisional application No. 62/157,471, filed on May 6, 2015.

(51) Int. Cl. H04B 1/7093; H04L 25/03; H04W 16/26; H04B 7/155; H04L 25/02; H03F 1/26; H04B 7/0413

(52) U.S. Cl. CPC H04B 1/7093; H04L 25/03038; H04W 16/26; H04L 25/03891; H04W 16/28; H04L 25/0204; H04L 25/0224; H03F 1/26; H04B 7/0413; H04B 7/15507

(57) ABSTRACT

This invention presents a repeater enhanced MU-MIMO wireless communication system comprising a BS, a plural of repeaters, and a plural of UEs, where a repeater estimates the channel between itself and its upper communication node in the system, a repeater computes equalization coefficients based on the estimation of the channel coefficients, and a repeater applies the equalization coefficients to reduce the channel delay spread or increase the coherence bandwidth of the channel between communication nodes containing the BS, the UEs, or the repeaters.

This application claims the benefit of U.S. Provisional Application No. 62/157,471, filed on May 6, 2015.

### FIELD OF INVENTION

This invention relates generally to novel relay designs to increase coherence bandwidth of wireless channels with Finite Impulse Response (FIR) filters in wireless systems.

### BACKGROUND

With the proliferation of mobile applications, there is an increasing demand for higher throughput of wireless systems at a staggering pace. Given the fact that the limited spectrum under 6-GHz is already crowded, millimeter Wave (mmWave) has emerged as a promising technology of future Fifth-Generation (5G) wireless systems [1].

Properly designed repeaters can play an important role in wireless systems. In Wireless Fidelity (WiFi) or Long Term Evolution (LTE) systems, repeaters are used to extend the coverage range. For mmWave, the role of repeaters is fundamentally different. Given the strong radio propagation directivity and large reflection loss of mmWave signals, repeaters are essential for seamless coverage [2]. Note that repeaters can be divided into two categories: Amplify-and-Forward Repeater (AFR) and Decode-and-Forward Repeater (DFR). Since the DFR introduces considerable propagation delay especially for multi-hop repeater scenario, AFR enhanced wireless systems offer advantages over DFRs. The energy efficiency of repeaters was studied in [3]. The problem of minimizing the number of repeaters and maximizing network utilities was studied in [4]. In [5], an iterative algorithm is developed for jointly designing the Receive/Transmit (Rx/Tx) Radio Frequency (RF)/baseband processors. It was demonstrated that multi-hop repeaters can greatly improve the connectivity versus single hop mmWave transmission in [6].

There have been previous inventions on utilizing repeaters in wireless systems. However, little attention has been paid to the impact of repeaters on wireless channel coherence bandwidth. Coherence bandwidth means all the sub-carriers within it share the similar channel characteristics, so that channel estimation only needs to be performed once for all the sub-carriers. In [7], it is demonstrated that multi-hop repeaters will make the channel coherence bandwidth narrower, but no methods were proposed to combat this issue of narrowed coherence bandwidth. Narrower coherence bandwidth means more resources (e.g., pilot spectrum and computation) have to be spent on channel estimation.

One embodiment of this invention is an innovative repeater design with an FIR-based channel equalizer to increase the coherence bandwidth of wireless systems. Based on the fact that the channels between repeaters are slow varying due to the repeaters being static (i.e., not moving), and thus have long coherence time, each repeater can adaptively equalize the channel using recently obtained channel estimates. With the equalized channels by this novel design, the energy sensitive User Equipments (UEs) can spend much less resources on channel estimation. For example, in an mmWave system with 4 repeaters and 100 UEs, all UEs can save half the resources in channel estimation, if the 4 repeaters are equipped with the FIR filters proposed in this invention.

Another embodiment of this invention is to equalize channels with beamforming with multiple antennas at transmitter or receiver. If the number of transmitter antennas is Nₜ and the number of receiver antennas is Nᵣ, the repeater would need Nₜ Nᵣ FIR filters. To reduce the complexity especially for systems with large numbers of antennas, this invention describes a method to first perform transmitter or receiver beamforming and then equalize the channels at each receiver antennas. Then, only Nᵣ FIR filters are needed for the repeater with Nᵣ antennas.

### BRIEF DESCRIPTION OF DRAWINGS

FIG. 1 shows the system model of repeaters.

FIG. 2 shows the system block of a single-antenna repeater.

FIG. 3 illustrates the structure of one equalization FIR filter.

FIG. 4 shows a time-domain example of equalizer.

FIG. 5 shows the simulation results of coherence bandwidth with different layers of repeaters.

FIG. 6 shows the simulation results of Bit Error Rate (BER) with different layers of repeaters.

FIG. 7 shows the simulation results for different subcarrier-grouping strategies.

FIG. 8 shows the diagram of Multiple-Input-Multiple-Output (MIMO) repeaters.

FIG. 9 shows the functional block diagram of an MIMO repeater with transmitter side beamforming algorithm.

FIG. 10 shows the functional block diagram of an MIMO repeater with receiver side beamforming algorithm.

FIG. 11 shows the block chart of receiver side Zero-Forcing (ZF) algorithm as an example.

FIG. 12 shows the simulation results of coherence bandwidth for MIMO repeaters.

FIG. 13 shows the flow chart of FIR parameter estimation without channel feedback.

FIG. 14 shows the flow chart of FIR parameter estimation with channel feedback.

### DETAILED DESCRIPTION

Reference may now be made to the drawings wherein like numerals refer to like parts throughout. Exemplary embodiments of the invention may now be described. The exemplary embodiments are provided to illustrate aspects of the invention and should not be construed as limiting the scope of the invention. When the exemplary embodiments are described with reference to block diagrams or flowcharts, each block may represent a method step or an apparatus element for performing the method step. Depending upon the implementation, the corresponding apparatus element may be configured in hardware, software, firmware or combinations thereof.

### Equalization Based on FIR Filter for One Pair of Transmitter-Receiver

The system model of the repeaters is shown in FIG. 1, where the direct path between the Base Station (BS) 1 and the UE 2 is blocked by obstacles 3, thus, the wireless signal propagates through the repeaters 4 to the UE.

Motivation of Equalization to Increasing Coherence Bandwidth: Channel frequency selectivity can be characterized by coherence bandwidth. Since sub-carriers within the coherence bandwidth have the similar channel, the UE or the BS only needs to estimate the channel once for all the sub-carriers within the coherence bandwidth. If the coherence bandwidth is wider, the system could spend less resource (e.g., pilot and computation) in channel estimation. As an example of LTE systems, there are totally 1200 sub-carriers. If the coherence bandwidth is 48 sub-carriers, the 1200 sub-carriers are divided into 25 groups, and each group only needs to conduct channel estimation once.

Assume that the transmitted signal is x(t), and the received signal y(t) through the wireless channel denoted by h(t) is then denoted as

y(t)=x(t)*h(t)=∫_{τ}^{∞}x(t−τ)h(τ)dτ, (1)

where * denotes convolution.

Let hₖ(t) denote the impulse response of the kth, k=1, 2, . . . K, hop, where the first hop begins from the BS, and the last hop ends at the UE. If there is no repeater during signal propagation, then K=1. Hence, the received signal through K hop of repeaters is given as

y(t)=x(t)*h₁(t)*h₂(t)* . . . *h_{K}(t)=x(t)*h^{r}(t), (2)

where h^{r}(t)=Πₖ₌₁^{K}hₖ(t) denotes the overall channel impulse response through K−1 repeaters.

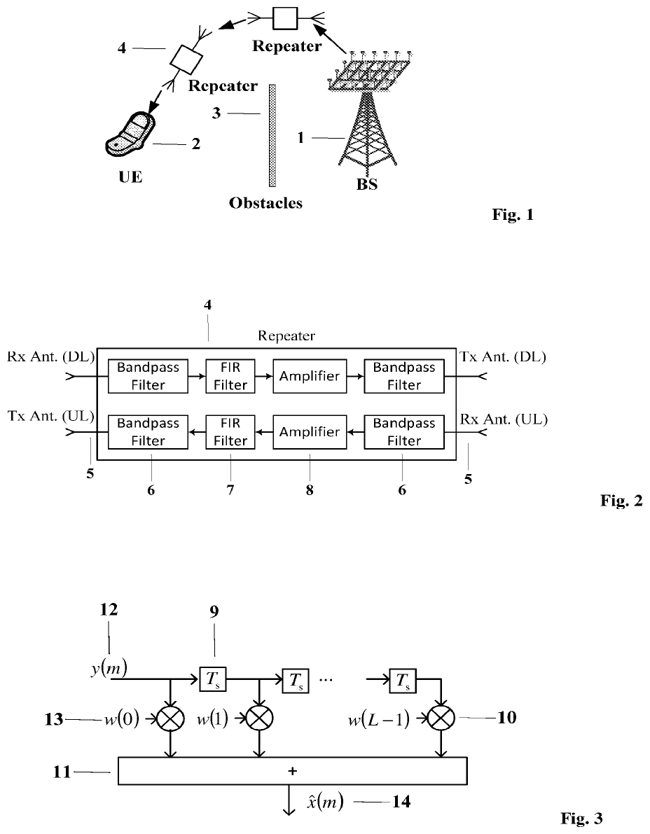

One embodiment of this invention is the repeater shown in FIG. 2, which consists of two antennas 5, two bandpass filters 6, an FIR filter 7, and an amplifier 8 for each direction, i.e., the downlink direction and the uplink direction. Note that the FIR filter may be placed after the amplifier. The FIR filter is designed to equalize the wireless channels. The system block of the FIR filter is illustrated in FIG. 3, which consists of L−1 delayers 9, L multipliers 10, and one adder 11, where there are L taps. The received signal y(m) 12 is first passed to the delayers. Then, the filter coefficients w(0), . . . , w(L−1) 13 are applied to the delayed signals by the multipliers. Finally, the filtered signals are summed by the adder to generate the output signal \hat{x}(m) 14. Note that the repeater might have other components to have other functions. For example, an attenuator and a phase shifter can be added into the repeater to create reciprocal uplink and downlink inside paths, as invented in our patent application PCT/US16/13744.

Assume that the impulse response of FIR filter on the ith repeater is wᵢ(t), i=1, . . . , K−1, then the final received signal can be written as a discrete time form

y(m)=x(m)*Πᵢ₌₁^{K-1}[hᵢ(m)*wᵢ(m)]*h_{K}(m), (3)

Where y(m)=y(mTₛ) with Tₛ being the sampling rate. Note that the destination of the last hop h_{K}(m) is the receiver, so there is no corresponding equalizer.

Another embodiment of this invention is the method to calculate the values of wᵢ (m) shown as follows. At the ith receiver, it estimates the channel hᵢ, then calculates wᵢ to equalize it. Let xᵢ^{P}(m) denotes the training pilot used to estimate hᵢ The reason that the channel hᵢ is frequency selective is that the received signal at the ith repeater y′ᵢ(m)=xᵢ^{p}(m)*hᵢ(m) consists some delayed replica of previous data xᵢ^{p}(m−1), xᵢ^{p}(m−2), . . . . If y(m) is not corrupted by previous data, then y′ᵢ(m)=xᵢ^{p}(m)hᵢ(m) and the channel is flat. Therefore, the problem is essentially designing a filter wᵢ so that the output \hat{x}ᵢ^{p}(m)=yᵢ′(m)*wᵢ(m) is close to xᵢ^{p}(m). Without loss of generality, assume that the pilot signal xᵢ^{p}(m) is the same for all the repeaters. For simplicity, let \hat{x}(m) and x(m) denote \hat{x}ᵢ^{p}(m) and xᵢ^{p}(m), respectively. Then, the goal of equalization is to choose wᵢ to minimize E(|\hat{x}(m)×(m)|²)

Assume that wᵢ has L taps, then,

\hat{x}(m)=w̅ᵢ(m)^{H}y̅′ᵢ(m), (4)

where

y̅′ᵢ(m)=[y′ᵢ(m−L+1),y′ᵢ(m−L+2), . . . , y′ᵢ(m)]^{T} (5)

and

w̅ᵢ(m)=[w*ᵢ(L−1),w*ᵢ(L−2), . . . , w*_{L}(0)]^{T}. (6)

To estimate the channel, the repeater does not need to decode the signals, but need to do analog-to-digital sampling. Like other RF components on the repeater (such as bandpass filter and amplifier), the FIR filter will introduce additional delay, but it is fixed and the maximum delay is the length of taps and can be designed to stay within the delay tolerance of the total channel, e.g., keeping the cyclic prefix under a maximum value. Therefore, the problem can be defined as the following:

minE(|\hat{x}(m)−x(m)|²)=min_{w̅}_{ᵢ}₍ₘ₎E[|w̅ᵢ(m)^{H}y̅′ᵢ(m)−x(m)|²]. (7)

Noticing the above is essentially a Minimum Mean Square Estimation (MMSE) problem, and the optimum solution satisfies that the estimation error w̅ᵢ(m)^{H}y̅′ᵢ(m)−x(m) is orthogonal to the observations y̅′ᵢ(m)

E{y′ᵢ(m−1)[w̅ᵢ(m)^{H}y̅′ᵢ(m)−x(m)]*}=0, (8)

with l=0, L−1. Then, the optimum solution is

w̅ᵢ(m)=Cov[y̅′ᵢ(m),y̅′ᵢ(m)]Cov[y̅′ᵢ(m),x(m)] (9)

where Cov denotes covariance.

Optionally, to guarantee that the input and output (of the FIR filter) signals have the same power, w̅ᵢ(m) can be normalized so that w̅ᵢ(m)^{H}w̅ᵢ(m)=1.

With the knowledge of x(m), the repeaters can compute the optimum wᵢ(m) based on the received signal y′ᵢ(m). Since the channel of each hop hᵢ(m) is equalized, the overall channel of repeater hops h₁(m)*h₂(m)* . . . *h_{K-1}(m) is equalized. Note that the repeaters can be trained based on the existing downlink/uplink pilot signals. Since the repeaters are static, the channel hᵢ has a long coherence time and this training can be done much less frequently than the downlink/uplink channel estimation. In addition, the repeaters are always less energy-sensitive than UEs. With this novel design, the energy-sensitive UEs can spend much less resources for channel estimation.

Note that it is not required that every repeater has an FIR filter for equalization. For example, the system can use the kth repeater to equalize the channel from transmitter to it through the k−1 repeaters.

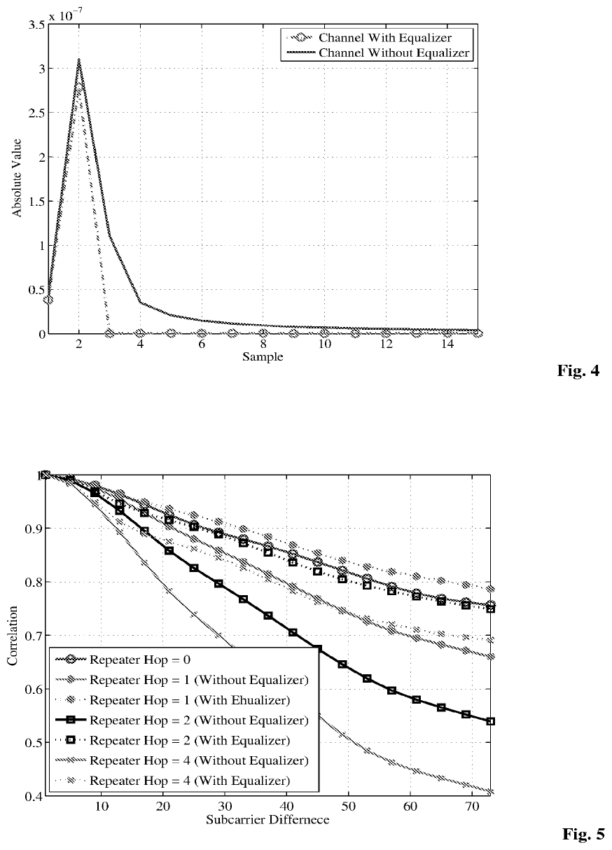

FIG. 4 shows one example of the FIR equalizer. The blue solid line denotes the time domain hᵢ generated using channel model in LTE standards [8]. The red dotted line is the channel after the FIR equalizer hᵢ*wᵢ. As shown in the figure, the channel impulse response with the equalizer is close to zero for m≥3, so that the channel is less disperse, leading to a wider coherence bandwidth.

The following simulation results show impact of the FIR equalizer on coherence bandwidth and BER. In the simulation, the delay values of the N taps of channel responses are generated based on the Poisson distribution. As verified by the mmWave campaign that “The distribution of power among the path clusters is well modeled via a 3GPP model” [2], the power levels of the N taps of channel responses are generated based on the exponential distribution [8]. Assume that the sampling rate at receiver/repeaters is 3.072 GHz, and the channel bandwidth is 2 GHz divided into 1200 subcarriers. Note that the values are chosen to achieve the same ratio of sampling rate over bandwidth as LTE [8]. The maximum tap of an FIR filter is L=50, i.e., 16.3 ns.

Coherence Bandwidth: FIG. 5 shows the comparison between coherence bandwidth with and without equalizer for different numbers of hops. The Signal-to-Noise (SNR) is set to be 30 dB. The coherence bandwidth is the maximum separation that the correlation is above a value η. For example, if η=0.8, the coherence bandwidth with “Repeater hop=0” is about 52 subcarriers. The results show that the coherence bandwidth decreases as the number of hops increases, and the proposed equalizer can significantly increase the coherence bandwidth, e.g., for “Repeater hop=4”, the coherence bandwidth with equalizer is about 40 subcarriers, which is double that of about 20 subcarriers without equalizer.

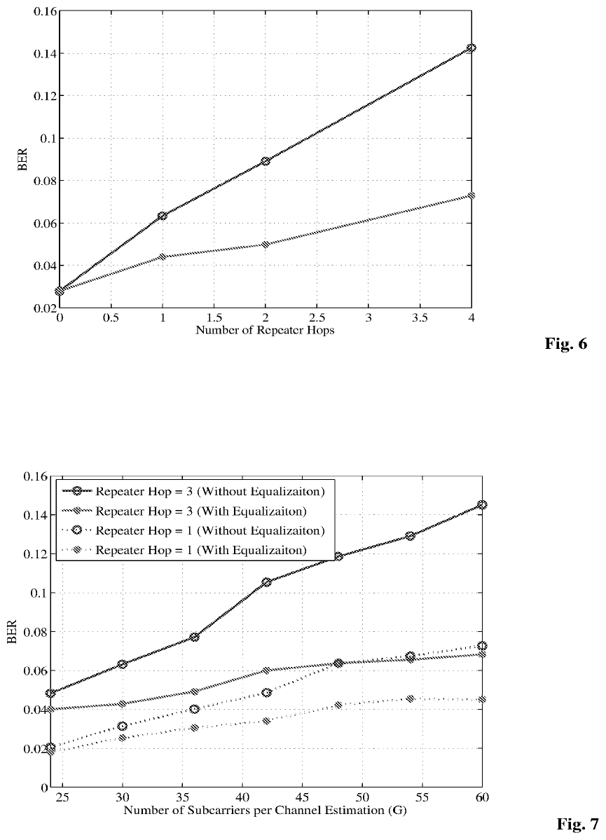

BER: FIG. 6 shows the BER with different numbers of hops. The frequency-domain Binary Phase-Shift Keying (BPSK) Orthogonal Frequency-Division Multiplexing (OFDM) signals are first transformed to the time domain, and then pass through the frequency selective channel. At the receiver, the channel of every 48 sub-carriers is estimated once, and the estimated channel is used to decode the BPSK signals of the 48 sub-carriers. To show the effect of channel selectivity, the channel estimation is assumed to be perfect, therefore if the 48 sub-carriers have the same channel, the BER would be 0. For simplicity, no forward error correction is applied. Let G denote the number of sub-carriers that use the same channel estimation for decoding. FIG. 7 shows the BERs for different sub-carrier grouping methods with different values of G. The x-axis denotes the value of G and the y-axis is the BER. It shows that more hops or a larger value of G leads to a higher BER. It also shows that the proposed equalizer is able to significant decrease BER, e.g., the BER with equalizer is about half that without equalizer for 4 hops with G=48.

### Equalization Based on FIR Filter for Multiple Transmitters-Receivers

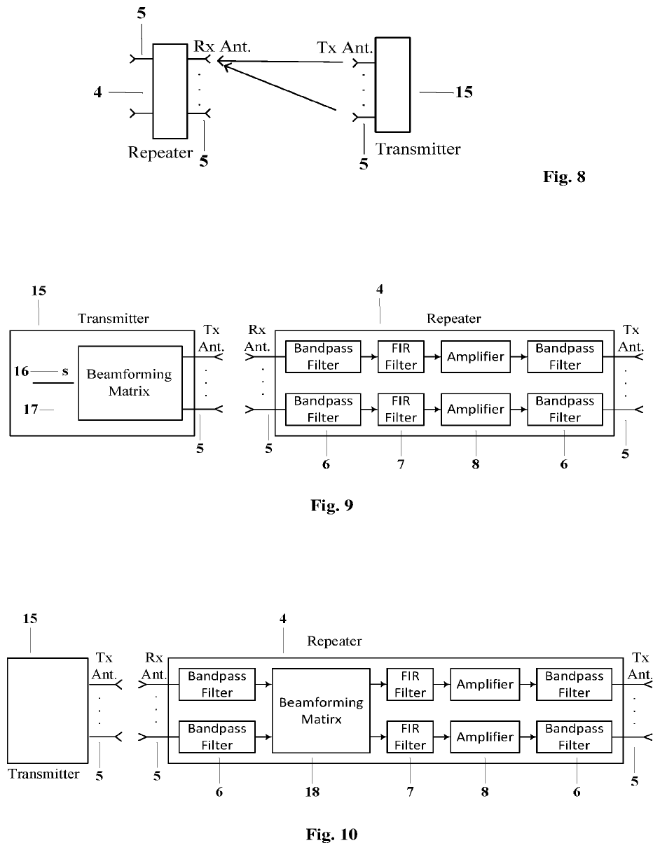

If there are multiple transmitter or receiver antennas, each antenna on a repeater 4 will receive signals from multiple antennas on the transmitter 15, which could be a BS, a UE, or anther repeater, as shown in FIG. 8. One embodiment of this invention is a method to first calculate the beamforming/precoding matrix at the transmitter, (if the number of transmitter antennas is larger than the number of receiver antennas) or to compute the beamforming/detection matrix at the receiver (if the number of transmitter antennas is equal or smaller than the number of receiver antennas), using methods such as ZF or MMSE, and then each receiver equalizes the overall channels. FIG. 9 shows the system level block diagram of transmitter side beamforming where the transmitted symbol vector s 16 is firstly precoded by a beamforming matrix 17 at the BS before being transmitted to the repeater, and FIG. 10 shows the block diagram of receiver side beamforming where the received signal vector after the bandpass filters is multiplied by a beamforming matrix 18 at the repeater before being passed to the FIR filters.

If the number of transmitter antennas is larger than the number of receiver antennas (repeaters in the first layer, i.e., the BS or the UE, has more antennas than repeaters), the transmitter side beamforming is needed. If the number of receiver antennas is equal or larger than the number of transmitter antennas, the receiver side beamforming is required to separate the data streams. If the transmitter has more antennas than the receiver, the transmitter needs to know the channel which can be obtained through uplink channel estimation (based on channel reciprocity) or channel estimation feedback from receivers to transmitters. Otherwise, only the receivers need to know the channel to separate data stream, and the channel can he estimated by downlink pilot transmission.

As shown in FIG. 8, there are Nₜ transmitter antennas, and Nᵣ receiver antennas. Assume that the transmitter has more antennas than the receiver. Then, the transmitter sends Nᵣ data sᵢ, i=1, . . . , Nᵣ, to the Nᵣ receiver antennas simultaneously where sᵢ is the desired signal for the ith antenna at the receiver, while others are interferences.

The precoding matrix is defined as x=Ps, where x=[x₁, x₂, . . . , x_{N}_{ₜ}]^{T} is the data vector at the Nₜ transmitter antennas, s=[s₁, s₂, . . . , s_{N}_{ᵣ}]^{T} is the data to be transmitted, and P is the precoding matrix, with p_{i,j} being the coefficient of mapping the jth data to the ith transmitter antenna. Let the jth column of P be pⱼ=[p_{1,j}, p_{2,j}, . . . , p_{N}_{ₜ}_{,j}]^{T}, then the received signal at the jth receiver antenna is yⱼ=pⱼ^{T}hⱼsᵢ where hⱼ=[h_{1,j}, h_{2,j}, . . . , h_{N}_{ₜ}_{,j}]^{T} with h_{i,j} being the channel from the ith transmitter antenna to the jth receiver antenna.

One procedure to compute the precoding matrix is described as follows. In the Time-Division Duplex (TDD) scenario, the Nᵣ receiver antennas send pilot signals to the Nₜ transmitter antennas, then the transmitter estimates the downlink channels based on channel reciprocity. In the Frequency-Division Duplex (FDD) version, the Nₜ transmitter antennas send pilot signals, and the Nᵣ receiver antennas estimate the channels and feed hack the channel estimates to the transmitter. Based on the channel estimation feedback, the optimum beamforming matrix can be computed, e.g., using ZF, MMSE, or other methods.

Then, the jth receiver antenna receives data through the equivalent channel h̅ⱼ=pⱼ^{T}hⱼ. The equalizer is then to equalize h̅ⱼ based on the same method in the single pair of antennas scenario described in the previous section.

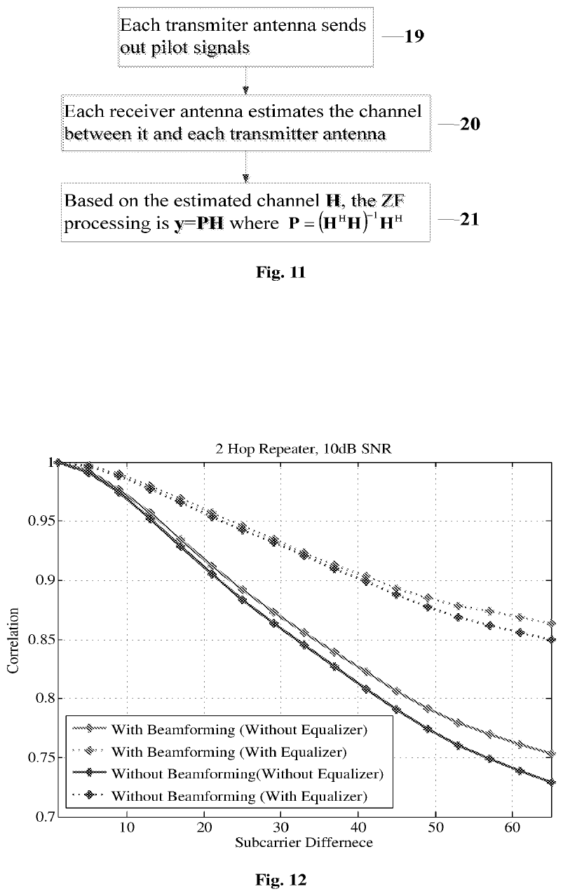

One embodiment of this invention is the transmitter or receiver beamforming algorithms to separate the data streams, so that the equalizer filter coefficients can be calculated for each data stream. One embodiment of this invention is that if the number of receiver antennas is equal or larger than the number of transmitter antennas, the receiver can separate the data streams through data processing such as ZF, MMSE, or other methods. In FIG. 11, the flowchart of receiver side ZF is shown as an example. After channel estimation, based on the estimated channel matrix, the ZF matrix P can be used to separate data streams. In this embodiment, the transmitter does not need to know the channel information, and the receiver antennas can estimate the channel based on training pilots from the transmitter. Specifically, first, each transmitter antenna sends out pilot signals 19. Then, each receiver antenna estimates the channel between it and each transmitter antenna 20. Next, based on the estimated channel matrix H, the ZF processing is y=PH where P=(H^{H}H)⁻¹H^{H} 21.

One difference from the single pair of antennas system is that the jth receiver antenna might receive interference (transmitted data other than sᵢ). If the precoding matrix is not perfectly calculated, then, the estimation of h̅ⱼ might not be accurate. In the following simulation, we assume imperfect beamforming with 10 dB Signal-to-Interference-plus-Noise Ratio (SINR) at the receiver. Simulation results in FIG. 12 show that the proposed algorithm also achieves good performance, i.e., equalization doubles the coherence bandwidth.

### Procedure of Equalization in Wireless Systems

This section describes the procedure of the channel equalization with repeaters in wireless systems, which includes the FIR parameter estimation, channel feedback, and UE channel estimation.

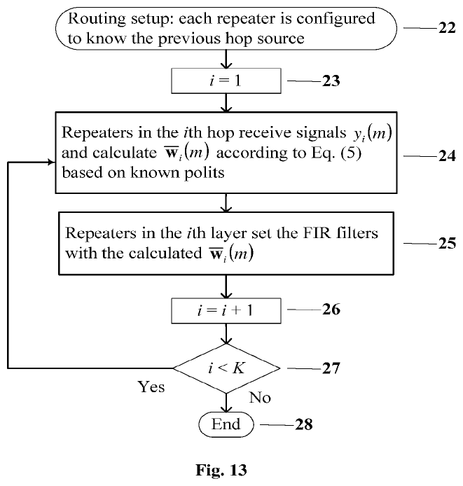

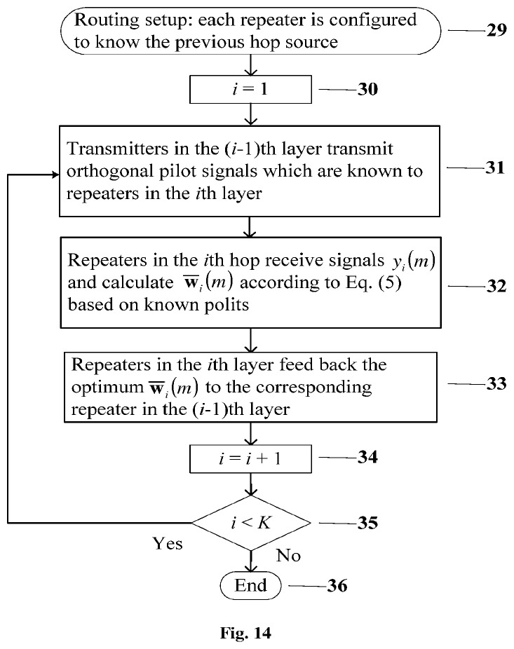

As described in previous sections, it is important to estimate the channels between repeater antennas and transmitter antennas, so that the optimum weighting of FIR filters can be calculated. As there might be many repeaters on the same hop, we define the repeaters receiving signals yᵢ (m) as the repeaters on the ith layer. Note that the channel estimation can be obtained either by direct downlink channel estimation (the repeater on the ith layer equalizes channels between the (i−1)th layer and the ith layer) or through channel feedback (the repeater on the ith layer equalizes channels between the ith layer and the (i+1)th layer). Note that the 0th layer is the BS for the downlink and the UE for the uplink. FIG. 13 shows the process of direct channel equalization. Specifically, the routing setup is first set that each repeater is configured to know the previous hop source 22. Then, starting from i=1 23, repeaters in the ith hop receive signals yᵢ(m) and calculate w̅ᵢ(m) according to Eq. (5) based on known pilots 24. Then, repeaters in the ith layer set the FIR filters with calculated w̅rᵢ(m) 25, before setting i=i+1 26. If i<K 27, then 24-26 are repeated. Otherwise, the process ends 28. FIG. 14 shows the process of channel equalization through feedback. Specifically, the routing setup is first set that each repeater is configured to know the previous hop source 29. Then, starting from i=1 30, transmitters in the (i−1)th layer transmit orthogonal pilot signals which are known to repeaters in the ith layer 31. Then, repeaters in the ith hop receive signals yᵢ(m) and calculate w̅ᵢ(m) according to Eq. (5) based on known pilots 32. Next, repeaters in the ith layer feed back the optimum w̅₁(m) to the corresponding repeater in the (i−1)th layer 33, before setting i=i+1 34. If i<K 35, then 31-34 are repeated. Otherwise, the process ends 35.

One embodiment of this invention is that the repeaters on the same layer use orthogonal codes (such as m-sequence) or spatial division to avoid interferences to the repeaters in the next layer. Another embodiment of this invention is that these pilots are transmitted in the system Guard Period (GP) for a TDD LTE system. In a LTE system, there are some dedicated OFDM symbols reserved for pilot transmission which can be used for filter coefficients calculations. The upper layer controls the signal propagation process, and then each repeater knows the previous hop sources, and their pilot signals. With orthogonal pilot sequence, each repeater in the ith layer only receives the signal from the desired transmitter in the (i−1)th layer. In addition to the code division, spatial division can also be used to avoid interference. The transmitters on some layer that are sufficiently separated in distance can be scheduled to use the same pilots, e.g., using in the same frequency and/or code at the same time to avoid interference. The transmitters on the same layer can also use high-directional antennas (common for mmWave systems) to send signals to different receivers with sufficient angular separations to avoid interference.

If the direct channel equalization is used, the repeaters in the first layer equalize the channels between them and the BS in the downlink scenario. However, in the uplink scenario, the first layer repeaters equalize the channels between them and the UEs. The channels between repeaters and UEs always have less coherence time than the channels between repeaters. Therefore, it is desired to use the equalization through feedback in the uplink scenario, so that the repeaters in the first layer equalize the channels between the repeaters in the first layer and repeaters in the second layer, and the repeaters in the last layer equalize the channel between them and the BS. This method guarantees that all the repeaters equalize the channels with long coherence time, to reduce system resource on equalization. After equalization, the total channel between the BS and the UE are still not perfectly flat, because the equalization at repeaters is not perfect and the channels between the UE and repeaters are not equalized. One embodiment of this invention is that the BS or the UE uses OFDM or other methods to estimate channels. For example, the system has a bandwidth of 2 GHz, and the channel is not flat over the 2 GHz bandwidth. However, if the 2 GHz bandwidth is divided into W subcarriers based on the OFDM technique, then the channel can be considered to be flat for every w subcarriers. Hence, the UE or the BS can estimate the channel for each group of w subcarriers. In this way, the UE or the BS has a good channel estimation in the overall 2 GHz channel.

The repeaters can achieve equalization using either one of the following two embodiments: (1) Direct amplify-and-forward mode: The FIR filter is constructed with tap delay lines, and each tap has one or more adjustable attenuators and/or phase shifters with values set to match the values of w̅ᵢ(m); or (2) Sample-and-forward mode: The repeater down-converted signals and obtain time-domain samples with an Analog-to-Digital Converter (ADC), then, the digital signals are passed through digital FIR filters, and the output of the filters are then converted to analog signals which are up-converted and sent out through repeater transmitters.

When all repeaters have obtained the optimum FIR settings, the communication between the BS and the UE is the same as without repeaters, since the repeaters operate in the amplify-and-forward mode. However, since the repeaters' inside paths might be asymmetric, special attention should be paid if the channel reciprocity is used to the downlink channel estimation. In summary, if the uplink and downlink channels of repeaters' inside symmetric, the FIR filters for the uplink and downlink have the same setting, then the overall channel from the BS to the UE is symmetric. If the uplink and downlink channels of repeaters' inside AFR paths are asymmetric, the channel estimation from the BS to the UE can be obtained through feedback.

Although the foregoing descriptions of the preferred embodiments of the present inventions have shown, described, or illustrated the fundamental novel features or principles of the inventions, it is understood that various omissions, substitutions, and changes in the form of the detail of the methods, elements or apparatuses as illustrated, as well as the uses thereof, may be made by those skilled in the art without departing from the spirit of the present inventions. Hence, the scope of the present inventions should not be limited to the foregoing descriptions. Rather, the principles of the inventions may be applied to a wide range of methods, systems, and apparatuses, to achieve the advantages described herein and to achieve other advantages or to satisfy other objectives as well.

### REFERENCES

[1]. T. S. Rappaport, S. Sun, R. Mayzus, H. Zhao, Y. Azar, K. Wang, G. N. Wong, J. K. Schulz, M. Samimi, and F. Gutierrez, “Millimeter Wave Mobile Communications for 5G Cellular: It Will Work!” IEEE Access, vol. 1, pp. 335-349, 2013.
[2]. S. Rangan, T. S. Rappaport, and E. Erkip, “Millimeter-Wave Cellular Wireless Networks: Potentials and Challenges,” Proceedings of the IEEE, vol. 102, no. 3, pp. 366-385, March 2014.
[3]. S. Yun, S. H. Jeon, J. K. Choi, and A.-S. Park, “Energy Efficiency of Relay Operation in Millimeter-Wave Mobile Broadband Systems,” in Proc. IEEE VTC Spring 2014, Seoul, Korea, May 2014.
[4]. G. Zheng, C. Hua, R. Zheng, and Q. Wang, “A Robust Relay Placement Framework for 60 GHz mmWave Wireless Personal Area Networks,” in Proc. IEEE GLOBECOM 2013, Atlanta, GA, USA, December 2013, pp. 4816-4822.
[5]. J. Lee and Y. H. Lee, “AF Relaying for Millimeter Wave Communication Systems with Hybrid RF/Baseband MIMO Processing,” in Proc. IEEE ICC 2014, Sydney, NSW, Australia, June 2014, pp. 5838-5842.
[6]. X. Lin and J. G. Andrews, “Connectivity of Millimeter Wave Networks With Multi-Hop Relaying,” IEEE Wireless Communications Letters, vol. 4, no. 2, pp. 209-212, April 2015.
[7]. T. Riihonen, S. Werner, and R. Wichman, “Hypoexponential Power-Delay Profile and Performance of Multihop OFDM Relay Links,” IEEE Transactions on Wireless Communications, vol. 9, no. 12, pp. 3878-3888, December 2010.
[8]. 3rd Generation Partnership Project; Technical Specification Group Radio Access Network; Evolved Universal Terrestrial Radio Access (E-UTRA); Further advancements for E-UTRA physical layer aspects (Release 9), 3GPP TR 36.814 v9.0.0, October 2010.

What we claim are:

1. A MIMO wireless communication system comprising one or more BS, one or more repeaters, and one or more UEs, wherein a repeater estimates the channel between itself and its upper communication node in the system, computes an equalization filter or equalization coefficients based on the estimation of the channel, and applies the equalization filter to improve the condition of the communication channel containing the one or more repeaters.

2. The system in claimed 1 wherein improving the condition of the communication channel comprises increasing the coherence bandwidth of the communication channel.

3. The system in claimed 1 wherein improving the condition of the communication channel comprises reducing the delay spread of the communication channel.

4. The system in claimed 1 further comprising that a plural of repeaters are placed in the coverage of a BS so that they forms a network that may contain more than one layer of communication nodes, wherein each repeater receives signals from its upper nodes that is either a BS or one or more repeaters and transmits signals to the lower nodes that is either one or more repeaters or one or more UEs in the downlink transmission.

5. The system claimed in 1 further comprising that the equalization of the channel between two neighboring nodes is implemented by either the upper node or the lower node, which is predefined by the system or informed through control information.

6. The system in claim 1 further comprising that a upper node transmits a pilot to the lower node and the lower node computes the equalization coefficients with the sampled received signals after the ADC, wherein the equalization coefficients are defined as a vector containing multiple complex-valued numbers.

7. The system in claim 6 further comprising that the pilot signals are transmitted in the GP of a TDD wireless communication system.

8. The system in claim 6 further comprising that some OFDM symbols is reserved for pilot transmission for equalization coefficient estimation, wherein the whole OFDM symbol is used for pilot sequence transmission when an OFDM symbol is reserved for pilot transmission.

9. The system in claim 1 wherein computing an equalization filter comprising computing equalization coefficients as solving an MMSE type problem and the solution has a form of a Wiener filter.

10. The system in claim 1 further comprising that the lower nodes feed back the received pilot signal after ADC or the estimated equalization coefficients to the upper node for equalization coefficient computation, wherein the equalization coefficients are defined as a vector containing multiple complex-valued numbers.

11. The system in claim 1 further comprising that orthogonal pilot sequences is employed by multiple nodes transmitting pilot signals in the downlink for equalization coefficients estimation simultaneously.

12. The system in claim 1 further comprising that the same pilot sequence(s) are shared by two or more nodes that are sufficiently separated in distance or are using highly direction antennas with sufficient angular separation.

13. The system in claim 1 further comprising that the transmitter side beamforming is applied when the number of antennas on the transmitter, which can be a BS, a UE, or a repeater, is larger than the number of antennas on the receiving repeater, before the channel equalization process, where the beamforming matrix is calculated based on the channel estimation acquired by the transmitter transmitting pilots to the receiver and the receiver feeding back the channel estimates, or the receiver transmitting pilots to the transmitter if channel reciprocity is valid.

14. The system in claim 1 further comprising that the receiver side beamforming is applied when the number of antennas on the receiving repeater is equal or larger than the number of antennas on the transmitter, which can be a BS, a UE, or a repeater, before the channel equalization process, where the beamforming matrix is calculated based on the channel estimation acquired by the transmitter transmitting pilots to the receiver.

15. The system in claim 1 further comprising that the communication node that computes the equalization coefficients applies the coefficients to the received RF signals when it works in the amplify-and-forward or the sample-and-forward mode in the downlink.

16. The system in claim 1 further comprising that the communication node that computes the equalization coefficients applies the coefficients to the transmitting RF signals when it works in the amplify-and-forward or the sample-and-forward mode in the uplink.

17. A repeater for using in a MIMO wireless communication system comprising a module for estimating the channel between itself and its upper communication node in the system, a module for computing an equalization filter based on the estimation of the channel, and a module for applying the equalization filter to improve the condition of the communication channel containing the repeater, wherein the MIMO wireless communication system comprises one or more BS, one or more repeaters, and one or more UEs.

18. The repeater in claimed 17 wherein improving the condition of the communication channel comprises increasing the coherence bandwidth of the communication channel.

19. The repeater in claimed 17 wherein improving the condition of the communication channel comprises reducing the delay spread of the communication channel.
